(19) United States
(12) Patent Application Publication
(10) Pub. No.: US 2009/0175066 A1
(43) Pub. Date: Jul. 9, 2009

(54) High-speed DRAM including hierarchical read circuits

(76) Inventor: Juhan Kim, San Jose, CA (US)

Correspondence Address: JUHAN KIM, 5890 W. WALBROOK DR., SAN JOSE, CA, 95129, US

(21) Appl. No.: 11/971,108

(22) Filed: Jan. 8, 2008

(51) Int. Cl. G11C 11/24; G11C 7/00

(52) U.S. Cl. 365/149; 365/189.15

(57) ABSTRACT

DRAM includes hierarchical read circuits with multi-divided bit lines, wherein a local read circuit receives an output from a memory cell through a bit line, a segment read circuit receives an output from one of multiple local read circuits through a segment read line, and a block read circuit receives an output from one of multiple segment read circuits through a block read line. Thus a voltage difference is converted to a time difference by the read circuits. In this manner, a time-domain sensing scheme is realized to differentiate high data and low data. For instance, high data is quickly transferred to a latch circuit through the read circuits with high gain, but low data is rejected by a locking signal based on high data as a reference signal. Additionally, various alternatives are described. And structures for the memory cell and layouts for the read circuits are illustrated.

### FIELD OF THE INVENTION

The present invention relates generally to integrated circuits, in particular DRAM (Dynamic Random Access Memory) including hierarchical read circuits with multi-divided bit line architecture.

### BACKGROUND OF THE INVENTION

For its high-density and relatively short cycle time, the DRAM (Dynamic Random Access Memory) is utilized extensively as a main memory in computer systems, even though DRAM requires refresh cycle to sustain stored data within a predetermined refresh time. As such, the DRAM constitutes a key component that holds sway on the performance of the computer system. Efforts of research and development have been under way primarily to boost the speed of the memory.

In the conventional DRAM, hierarchical bit line architecture is applied to achieve high-speed operation, as published, “Hierarchical bitline DRAM architecture system” as U.S. Pat. No. 6,456,521, and “A hierarchical bit-line architecture with flexible redundancy and block compare test for 256 Mb DRAM” in VLSI Circuits, Digest of Technical Papers, May 1993. pp 93-94. More specifically, FIG. 1 illustrates a circuit diagram of the conventional DRAM. The memory cells 101 and 102 are connected to a local bit line 131, and the memory cells 103 and 104 are connected to another local bit line 133, where the plate of capacitor is connected half VDD (supply voltage) typically. Local bit lines 131 and 133 are connected to a global bit line (BLT) 111 and another global bit line (BLB) 112 through transfer transistors 121 and 123, respectively. And more local bit lines 132 and 134 are connected to the global bit lines 111 and 112, respectively. When reading, one of memory cells is selected, and the selected cell charges or discharges the local bit line while the local bit lines and the global lines are released from pre-charge node 117, such that equalizer transistor 113, pre-charge transistors 114 and 115 are turned off by control signal 116. Thus, one of global bit lines is also charged or discharged by the selected memory cell. After then sense amplifier 141 is activated to generate read output 142. However, the selected global bit line is slowly changed because the selected memory cell should drive local bit line and global bit line through transfer transistor, where the global bit line increases total capacitance. Moreover, the storage capacitor in the memory cell should be relatively big in order to absorb the charges from the global bit line, which is one of major obstacles to reduce the DRAM cell. As a result, access time is also slow because of heavy global bit line, which increases propagation delay and sensing time for the sense amplifier.

And more prior art is shown, “High speed DRAM local bit line sense amplifier”, U.S. Pat. No. 6,426,905, wherein a local sense amplifier detects a change of charge out of an input node, and comprises a first current source and a first field effect transistor. The current source is provided for removing charge from the input node. The field effect transistor includes (i) a source coupled to the input node, (ii) a gate electrode coupled to a first voltage, and (iii) a drain coupled to one side of a first capacitor, to an output node, and to a pre-charge circuit for setting the voltage of the output node to a second voltage, providing a voltage difference between the drain and source of said first transistor. The other side of the capacitor is coupled to ground. However, many transistors (seven transistors) for each local sense amplifier are required, and also a capacitor is used for configuring the local sense amplifier, which increase chip area.

In this respect, there is still a need for improving the dynamic random access memory, in order to achieve fast access and reduce area. In the present invention, hierarchical read circuits are used for reading the multi-divided bit lines with a time-domain sensing scheme to compare the output from the memory cell through multi-stage read circuits, where a reference signal is generated by reference memory cells in order to compare high voltage data and low voltage data, because one of data from the memory cell (fast data) is reached to a latch circuit through the multi-stage read circuits with high gain while another data (slow data) is rejected by the reference signal. And multi-divided bit line reduces the parasitic capacitance of the local bit line, which realizes fast operation.

And the memory cell can be formed on the surface of the wafer. And the steps in the process flow should be compatible with the current CMOS manufacturing environment. Alternatively, the memory cell can be formed from thin film polysilicon layer, because the lightly loaded bit line can be quickly discharged by the memory cell even though the thin film transistor can flow relatively low current. In doing so, multi-stacked memory is realized with thin film transistor, which realizes high density memory within the conventional CMOS process with additional process steps for forming the memory cell, because the conventional CMOS process is reached to the scaling limit for fabricating the memory cell on the surface of the wafer. More detailed explanation will be followed as below.

### SUMMARY OF THE INVENTION

In order to realize high speed DRAM (Dynamic Random Access Memory), bit lines are multi-divided for reducing parasitic loading of the bit line, so that the divided bit line is quickly charged or discharged when reading and writing, which realizes fast read and write operation. In particular, hierarchical read circuits are introduced for reading the memory cell through the divided bit line such that a local read circuit receives an output from a memory cell through a bit line, a segment read circuit receives an output from one of multiple local read circuits through a segment read line, and a block read circuit receives an output from one of multiple

In order to place the local read circuit and the segment read circuit next to the memory array with small area repeatedly, a few transistors are used for configuring the read circuits. And the local read circuit has high gain with wider channel MOS transistor than that of the memory cell. Furthermore, the segment read circuit has higher gain than that of the local read circuit. For instance, a wider channel MOS transistor or a strong bipolar transistor can be used as an amplify transistor for the segment read circuit, which realizes fast read operation. And the current consumption is lower than that of the conventional sensing circuit because a feedback circuit cuts off immediately the current path through the block read circuit after latching the data during read.

By the read circuits, a voltage difference in the bit line is converted to a time difference as an output of the block read circuit with gain of the read circuits. In this manner, a time-domain sensing scheme is realized to differentiate high data and low data. For instance, high data is quickly transferred to a latch circuit through the read circuits with high gain, but low data is rejected by a locking signal based on high data as a reference signal.

More specifically, a reference signal is generated by one of fast changing data with high gain from reference cells, which signal serves as a reference signal to generate a locking signal for a latch circuit in order to reject latching another data which is slowly changed with low gain, such that high voltage data is arrived first while low voltage data is arrived later, or low voltage data is arrived first while high voltage data is arrived later depending on configuration. The time-domain sensing scheme effectively differentiates low voltage data and high voltage data with time delay control, while the conventional sensing scheme is current-domain or voltage-domain sensing scheme. In the convention memory, the selected memory cell charges or discharges the bit line, and the changed voltage of the bit line is compared by a comparator which determines an output at a time. There are many advantages to realize the time-domain sensing scheme, so that the sensing time is easily controlled by a tunable delay circuit, which compensates cell-to-cell variation and wafer-to-wafer variation, such that there is a need for adding a delay time before locking the latch circuit with a statistical data for all the memory cells, such as mean time between fast data and slow data. Thereby the tunable delay circuit generates a delay for optimum range of locking time. And the read output from the memory cell is transferred to the latch circuit through a returning read path, thus the access time is equal regardless of the location of the selected memory cell, which is advantageous to transfer the read output to the external pad at a time.

Furthermore, the current flow of the cell transistor can be reduced because the cell transistor only drives a lightly loaded local bit line, which means that the cell transistor can be miniaturized further. Moreover, the present invention can overcome scaling limit of the conventional CMOS process with multi-stacked memory cell structure including thin film transistor because the memory cell only drives lightly loaded bit line even though thin film polysilicon transistor can flow lower current. There are almost no limits to stack multiple memory cells as long as the flatness is enough to accumulate the memory cell.

Furthermore, various alternative configurations are described for implementing the hierarchical read circuits. And, example memory cell layout and cross sectional views are illustrated to minimize cell area. The fabrication method is compatible with the conventional CMOS process for realizing planar memory cell including the single-crystal-based transistor. Alternatively, additional steps are required for adding the bipolar amplify transistor. And LTPS (low temperature polysilicon) layer is used for forming thin film transistor as a pass transistor of the memory cell, which realizes multi-stacked memory cells in order to overcome the scaling limit.

Still, furthermore, various capacitors can be used as the capacitor storage element. For example, DRAM uses ordinary dielectric material, such as silicon dioxide, silicon nitride, Ta2O5, TiO2, A12O3, TiN/HfO2/TiN(TIT), and Ru/Insulator/TiN(RIT). And PIP (Polysilicon Insulator Polysilicon) capacitor structure and MIM (Metal Insulator Metal) capacitor structure can be used for forming the capacitor. Alternatively, ferroelectric capacitor can be used as the capacitor, such as lead zirconate titanate (PZT), lead lanthanum zirconium titanate (PLZT), barium strontium titanate (BST), and strontium bismuth tantalate (SBT), where dielectric constant of ferroelectric capacitor is typically high so that effective capacitance is increased.

These and other objects and advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings which are incorporated in and form a part of this specification, illustrate embodiments of the invention and together with the description, serve to explain the principles of the invention.

FIG. 1 illustrates a dynamic random access memory, as a prior art.

FIG. 2 illustrates a time-domain sensing scheme for DRAM including a local read circuit and a segment read circuit, according to the teachings of the present invention.

FIG. 3A illustrates an I-V curve of the local read circuit when reading, FIG, 3B illustrates charging time of the block read line, FIG, 3C illustrates read output for data “1” and data “0”, FIG. 3D illustrates read data “1” timing diagram, and FIG. 3E illustrates read data “0” timing diagram, according to the teachings of the present invention.

FIG. 4 illustrates the time-domain sensing scheme including a current mirror as a block read circuit, according to the teachings of the present invention.

FIG. 5 illustrates the time-domain sensing scheme for configuring a big memory bank, according to the teachings of the present invention.

FIG. 6 illustrates alternative configuration with comparator as a block read circuit, according to the teachings of the present invention.

FIG. 7A illustrates a tunable delay circuit, FIG. 7B illustrates a delay unit of the tunable delay circuit, FIG. 7C illustrates a related fuse circuit of the tunable delay circuit, and FIG. 7D illustrates a selector circuit, according to the teachings of the present invention.

FIGS. 8A, 8B, 8C and 8D illustrate an example layout for the memory cell, according to the teachings of the present invention.

FIG. 9 illustrates more detailed bit line structure for a memory segment, according to the teachings of the present invention.

FIGS. 10A, 10B and 10C illustrate an example layout for the read circuits, FIG. 10D illustrates the related bipolar amplify transistor, and FIG. 10E illustrates the related read circuits for explaining the layout, according to the teachings of the present invention.

FIG. 11 illustrates an example cross sectional view for the memory cell for obtaining high capacitance, according to the teachings of the present invention.

FIG. 12A illustrates an example cross sectional view for the memory cell including flat plates, and FIG. 12B illustrates an example cross sectional view for the memory cell including three plates, according to the teachings of the present invention.

FIG. 13 illustrates a related cross sectional view for stacking the memory cell (as shown in FIG. 12B) on peripheral circuits, according to the teachings of the present invention.

FIGS. 14A, 14B and 14C illustrate an example cross sectional view for the memory cell including bottom capacitor, according to the teachings of the present invention.

FIG. 15 illustrates a related cross sectional view for stacking the memory cell (as shown in FIG. 14C) on peripheral circuits, according to the teachings of the present invention.

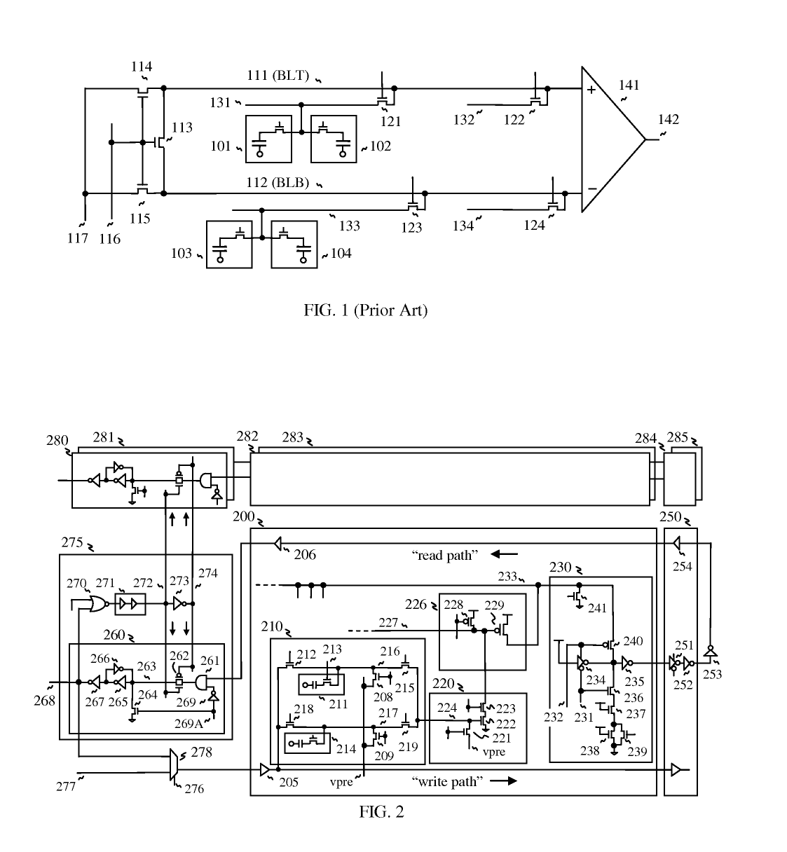

### DETAILED DESCRIPTION OF PREFERRED EMBODIMENT(S)

Reference is made in detail to the preferred embodiments of the invention. While the invention is described in conjunction with the preferred embodiments, the invention is not intended to be limited by these preferred embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

The present invention is directed to DRAM including hierarchical read circuits, as shown in FIG. 2, wherein a memory block 200 is composed of a memory segment 210, a local read circuit 220, a segment read circuit 226, a block read circuit 230, a write buffer 205 and a read buffer 206. The memory segment 210 comprises a plurality of memory cell connecting to bit lines 216 and 217, write transfer transistors 212 and 218 writing data to memory cells 211 and 214 respectively, bit line pre-charge transistors 208 and 209 pre-charging the bit lines. And the bit lines are divided into short lines in order to reduce capacitive loading, such as half, one-fourth or one-eighth, compared with the conventional memory. By reducing capacitive loading, the memory cell drives only lightly loaded bit line during read, which means that the memory cell can be miniaturized further. However, by dividing bit lines into short lines, more read circuits are required. Thus, each read circuit should be reduced with a few transistors for inserting between the divided memory arrays. To do so, hierarchical read circuits are used for reading the segmented memory array such that the local read circuit 220 is connected to a common line 224, and the common line is connected to the local bit lines 216 and 217 through read transfer transistors 215 and 219 respectively, where a pre-charge transistor 221 is connected to the common line 224 for pre-charging, a local amplify transistor 222 receives a voltage output from one of local bit lines 216 and 217 through the common line 224, while one of the read transfer transistors 215 and 219 is turned on, and a select transistor 223 is serially connected to the local amplify transistor 222. Thus the select transistor 223 enables to generate an output to the segment read circuit 226 through a segment read line 227, so that the segment read circuit 226 receives the output from the local read circuit 220. Then, a segment amplify transistor 229 having wide channel strongly charges a block read line 233 when the local read circuit 220 is turned on and a reset transistor 228 of the segment read circuit 226 is turned off. Hence, a current path is set up from the segment amplify transistor 229 to active load devices including 237 and 238 in the block read circuit 230 when block select transistors 236 and 240 are turned on by block select signals 231 (high) and 232 (low). Otherwise no current path is set up when the local read circuit 220 is not turned on.

During standby, the local bit lines 216 and 217 are pre-charged to VPRE (near half VDD) voltage by pre-charge transistors 208 and 209, respectively. And the common line 224 is also pre-charged to VPRE voltage by the pre-charge transistor 221. Then, the pre-charge transistors are turned off to release the selected bit line 216 for reading data. Then the read transfer transistor 215 is turned on, and the write transfer transistor 212 keeps turn-off state. After then, the memory cell 211 is turned on by a word line 213, so that the selected local bit line is changed by stored charges of the memory cell. Thus, the changed voltage of the local bit line 216 is transferred to the local amplify transistor 222 through the transfer transistor 215 and the common line 224. And the local amplify transistor 222 amplifies the bit line voltage when the select transistor 223 is turned on. When the memory cell stores data “1”, the local bit line voltage is slightly raised from the pre-charged voltage (half VDD voltage, for example, 500 mV), such that the selected local bit line 216 is raised to 600 mV from 500 mV, for instance. In contrast, when the memory cell stores data “0”, the local bit line voltage is slightly lowered from the pre-charged voltage, such that the selected local bit line is lowered to 400 mV from 500 mV.

When the selected memory cell stores data “1”, the (NMOS) local amplify transistor 222 sets up strong current path to a segment read line 227 which is released from pre-charge state. Hence, the segment read line is quickly discharged near ground voltage because the segment read line 227 is floating with capacitive loading of the wire. As a result, the (PMOS) segment read circuit 226 quickly charges the block read line 233. Otherwise, when the selected memory cell stores data “0”, the local amplify transistor 222 sets up weak current path to the segment read line 227. Hence, the segment read line is very slowly discharged near ground voltage. Consequently, the segment read circuit 226 very slowly charges the block read line 233.

When reading data “1”, the block read line 233 is raised near VDD voltage by the segment read circuit 226, because block select transistors including PMOS transistor 240 and NMOS transistor 236 are turned on for the selected block 200, and the strength of the segment read circuit 226 is much stronger than that of pull-down transistors 236, 237 and 238. Alternatively, the pull-down strength is tunable with select transistor 239 comprising a wide channel transistor, and more selectable transistors can be added even though the drawing includes only one tunable pull-down transistor. Thereby, a common-source amplifier is composed of the segment amplify transistor 229 as an amplify device and the pull-down transistors as active loads. Thus, a read inverter 235 receives the output of the amplifier, while a tri-state inverter 234 is turned off for the selected block but another tri-state inverter 251 in the unselect block 250 is turned on to bypass the read output, such that an output multiplexing circuit is consisted of the amplifier and the tri-state inverter. Hence the read output of the read inverter 235 is transferred to a latch circuit 260 through a read path including the tri-state inverter 251, inverters 252 and 253, non-inverting buffers 254 and 206. In this manner, one data is transferred to the latch circuit early, but another data is transferred later, such that data “1” is arrived first and data “0” is arrived later because of local bit line voltage difference. Thus data “1” serves as a reference signal to reject latching data “0” to the latch circuit for differentiating the fast data and the slow data in a time domain. More detailed explanation will be followed as below.

And the read path includes a returning path, so that the arriving time to the latch circuit is almost same regardless of location of the selected memory cell, as long as the word line receives the address inputs from the latch circuit side and delay time of the address inputs is similar to the read path including multiple buffers (not shown). Furthermore, the returning path is inverted by inverter 253 which compensates the strength of the rise time and the fall time of the buffers. Without inverting, the long read path includes only rising delay, because the rise time and the fall time are not equal in CMOS buffer. Alternatively, the read inverter 235 can be a Schmidt trigger to reject low voltage more effectively, which circuit can be composed of the conventional circuit techniques as published U.S. Pat. Nos. 4,539,489 and 6,084,456, thus detailed schematic is not described in the present invention, wherein an inverting type Schmidt trigger can be used for this application.

In the latch circuit 260, the read output changes the latch node 263 and output 268 to high from low through inverters 265 and 267 because the latch node 263 is pre-charged to low by NMOS 264 and an AND gate 261 with inverter 269. And a pre-charge control signal 269A controls NMOS 264 and inverter 269, before activated. After then, the read output is stored in the latch node 263 with cross coupled inverters 265 and 266. And the output 268 changes NOR gate 270 to low, so that the transmission gate 262 is locked by signal 272 and 274 which are transferred from the output 268 through a tunable delay circuit 271 and inverter 273. Simultaneously, latch circuits 280 and 281 are also locked by the signal 272 and 274, where latch circuits 280 and 281 are composed of same circuits as the latch circuit 260. In doing so, the output 268 serves as a reference signal, which is generated by the reference memory cells, such as the memory cells 211 and 214 which store data “1”. Adding delay circuit 271, the reference signal serves as a locking signal, where the delay circuit is tunable for differentiating data “1” and data “0”, more effectively, because data “1” is arrived before data “0” is arrived.

Thus, the latch circuit 260 and the delay circuit 271 configure a latch control circuit 275, in order to generate the locking signal. More detailed delay circuit will be explained as below. And the NOR gate 270 is used to generate the reference signal even though one of reference cells is failed, where more than one reference column is added to the memory block even though the drawing illustrates only one reference memory column including the latch circuit 260. In this manner, the read outputs from the main memory block 282, 283, 284 and 285 are stored to the latch circuits 280 and 281 by the locking signals 272 and 274 when activated.

Furthermore, the read access time is faster than that of the conventional memory, such that multi-divided bit line architecture is introduced in order to reduce the parasitic capacitance of local bit line. And the strong read circuits transfer the read data to the block read circuit quickly with high gain. As a result, the sensing scheme including the locking signal is referred to as a “time-domain sensing scheme” with hierarchical read circuits. And also the local read circuit includes a few transistors in order to place next to the memory cell array. Moreover, the segment read circuit includes only two transistors, which circuit can be placed in the memory array to receive one read output from multiple local read circuits through the segment read line. Hence, the block read circuit is placed at the edge of the memory block to receive one of outputs from multiple segment read circuits through the block read line.

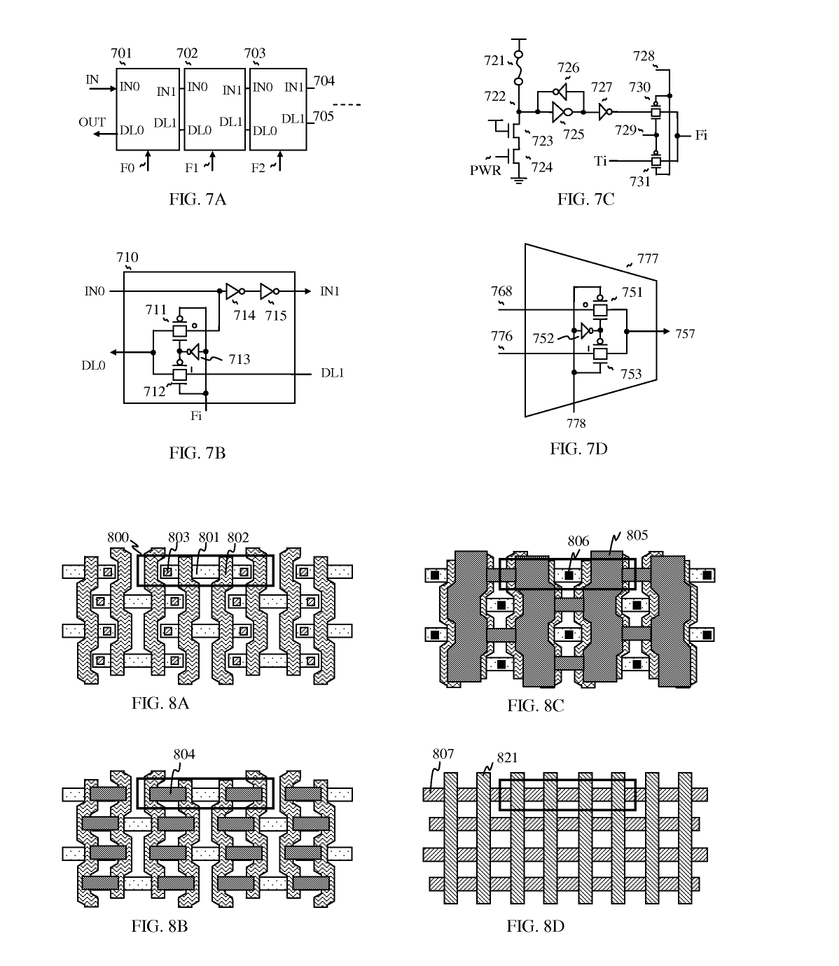

To write data, the write buffer 205 receives output of a data selector 278 (detailed circuit is shown in FIG. 7D), and drives the bit line through one of write transfer transistors 212 and 218, while the read circuits including the segment read circuit 226 and the block read circuit 230 are not activated. Before write, write data is determined by a selector circuit 278 wherein a column decoder signal 276 decides output of the selector 278, such that external data input 277 is selected in order to modify the stored data of the memory cell, or the read output 268 is selected in order to write back, because the stored data in the memory cell is disturbed during read. Furthermore, the write back operation is used to refresh the stored data periodically, because the stored charges are reduced by leakage current.

Another aspect for the operation is that the word line voltage affects the read operation and the write operation, such that the transfer transistors including the word line of the memory cell, the write transfer transistor and the read transistor can be raised to VDD (supply voltage). Thus, the storage node of the memory is pull-up to VDD−VT level because of NMOS threshold voltage (VT) drop during write, which affects the read operation as well. In order to avoid NMOS threshold voltage drop, the word line and transfer transistor voltage can be raised to higher than VDD+VT level as the conventional DRAM, alternatively. Hence all the signals are reached to full VDD level when write, which enables to achieve fast access with more charges to the storage node and low impedance of the transfer transistors.

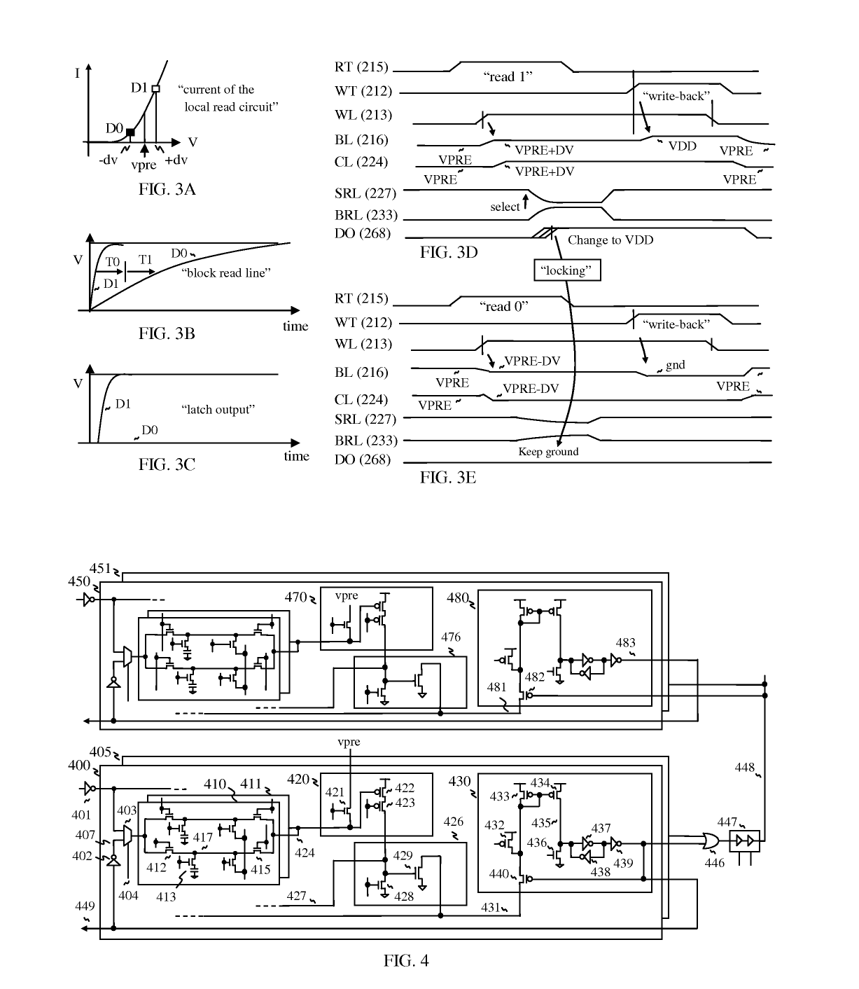

Referring now to FIG. 3A in view of FIG. 2, I-V curve of the local amplify transistor 222 is illustrated, wherein data “1” (D1) shows much higher current than that of data “0” (D0) when activated. For example, the local bit line voltage is slightly raised from the pre-charged voltage at half VDD level (500 mV) to 600 mV when the memory cell stores data “1”. On the contrary the selected local bit line is slightly lowered to 400 mV from 500 mV. Then the select transistor 223 is turned on in order to measure the current through the read transistor 222, thus the current through the read transistor 222 is provided to the segment amplify transistor 229, which transistor amplifies with high gain. In FIG. 3B, charging time for the heavily loaded block read line 233 is illustrated, wherein the block read line 233 is quickly charged when data “1” (D1) is read. On the contrary, the block read line 233 is slowly charged when data “0” (D0) is read. In FIG. 3C, the read output 268 is illustrated, such that data “1” (D1) is raised to high within a predetermined time, but data “0” (D0) is not arrived because it is rejected to be latched as explained above.

Referring now to FIG. 3D in view of FIG. 2, detailed timing diagram for reading data “1” is illustrated. In order to read data, the read transfer transistor 215 is turned on, and the local bit line (BL) 216 and the common line (CL) 224 are released from pre-charge state. After then the word line (WL) 213 is raised to predetermined voltage in order to measure the stored charge in the memory cell 211. Hence, the local bit line (BL) 216 is raised to VPRE+DV, which strongly turns on the local read circuit. Thus, the segment read line (SRL) 227 is discharged to ground voltage, which turns on the segment read circuit 226. As a result, the block read line 233 is quickly charged near VDD level by the segment read circuit 226 even though the pull-down transistors 236, 237 and 238 resist to change the block read line, because the pull-up strength of the segment read circuit 226 is much stronger than that of the pull-down transistors, while the block select transistor 236 and 240 are turned on for the selected block 200. Pulling up the block read line 233 near VDD voltage, the output of read inverter 235 is changed to low from high, and which output is transferred to output node (D0) 268 through the returning read path. During read operation, there is no phase control such that the memory cell data is immediately transferred to the output node 268 through the read path. More specifically, the segment select transistor 223 is turned on to measure the local bit line voltage after the stored charges of the memory cell are re-distributed to the local bit line. Then, the block read circuit 230 waits until the read circuit 226 charges the block read line 233, even though the block read circuit is activated around same time with the segment read circuit to reduce a waiting time. When the segment read circuit charges strongly the block read line 233, the block read circuit detects the change with the amplifier including the pull-down transistor as active loads, and transfers the read output to the latch circuit. Otherwise, the block read circuit keeps the pre-charge state, so that read control is relatively simple, which also realizes fast access with no extra waiting time. Furthermore, the local amplify transistor 222 and the segment amplify transistor 229 can include lower threshold voltage MOS transistor than that of other peripheral circuits, in order to achieve fast read. After reading the data “1”, writing back operation is illustrated for keeping or refreshing the read data, wherein the write transfer transistor 212 is turned on to transfer the output of the write buffer 205. For refreshing the read data, the write buffer sends high voltage (same data), so that the high voltage is transferred to the storage node of the memory cell while the word line is turned on but the read circuits are de-activated. After writing, all the control signals are returned to pre-charge state or standby mode.

Referring now to FIG. 3E, detailed read timing diagram for reading data “0” is illustrated, wherein the local read circuit 220 slowly discharges the segment read line 227, which also slowly charges the block read line 233 because the common line (CL) 224 is slightly lowered to VPRE-DV level from pre-charge voltage VPRE. Hence the read output 268 is not changed, because the locking signal 272 and 274 locks the latch 280 and 281 in order to reject the late signal based on data “0”. To do so, a reference signal is generated by fast data (data “1”) with delay time T0 in FIG. 3B, so that the timing margin T1 in FIG. 3B is defined to reject slow data (data “0”). After reading the data “0”, writing back operation is executed for keeping or refreshing the read data, wherein the write transfer transistor 212 is turned on to transfer the output of the write buffer 205. For refreshing the read data, the write buffer sends low voltage (same data), so that the low voltage is transferred to the storage node of the memory cell while the word line is turned on but the read circuits are not activated. After writing, all the control signals are returned to pre-charge state or standby mode.

In this manner, the time-domain sensing scheme differentiates data “1” and data “0” within a predetermined time domain. For example, the time-domain sensing scheme is more useful for the page mode operation, such that a word line is asserted for long time with a row address while column addresses are changed frequently. When asserting a word line for long time, high data quickly changed and reached to the latch circuit, which generates a locking signal. And also low data is very slowly changed within the long cycle time, but the locking signal effectively rejects low data to be latched to the latch circuit. In other words, fast cycle memory (with no page mode), for example, high-speed embedded memory, does not require the locking signal which is generated by the reference signal based on reference cells, because low data is not reached to the latch circuit within a short cycle. Thus, an enable signal from a control circuit is used to control the latch circuit, which does not require reference cells and related circuits.

Alternatively, reverse configurations equally work such that the local read circuit is composed of PMOS transistors, the segment read circuit is composed of NMOS transistors and the block read circuit is reversely composed of pull-down transistors (not shown). And there are various modifications and alternatives for configuring the read circuits, in order to read data from the memory cell through the multi-divided bit line.

In FIG. 4, alternative configuration including a current mirror as a block read circuit is illustrated. A memory block 400 includes a memory segment 410 and 411, a local read circuit 420, a segment read circuit 426, a block read circuit 430, a write buffer 402, and a write selector 403. The write path includes a write selector 403 which selects external data 401 or internal data 407 through an inverter 402 to write or refresh with column control signal 404. The local read circuit 420 is composed of a pre-charge transistor 421, a read transistor 422, a select transistor 423, and the segment read circuit 426 includes a reset transistor 428 and a segment amplify transistor 429. And the block read circuit 430 is composed of a current mirror and a latch circuit, wherein the current mirror is composed of a pull-up transistor 433 and a current mirror (repeater) transistor 434, and the latch circuit is composed of two cross coupled inverters 437 and 438. The pull-up transistor 433 is connected to the segment read circuit 426 through the block read line 431 and PMOS switch 440, and a pre-charge transistor 432 is connected to the pull-up transistor 434. In order to read a memory cell 413 in the bit line 417, pre-charge transistors are turned off to release the bit line 417 and the common line 424, then read transfer transistor 415 is turned on but write transfer transistor 412 keeps turn-off state. After then, the memory cell 413 is turned on to measure the stored voltage. Hence, the local bit line 417 is slightly higher or lower than VPRE voltage, which strongly or weakly turns on the local read circuit. And the segment read circuit 426 quickly or slowly pulls down the block read line 431 while the switch 440 is turned on and the pre-charge transistor 432 is turned off.

When reading data “1”, the stored voltage in the memory cell is inverted because the PMOS local read circuit 420 inverts to recover the polarity, such that the latch node 435 is quickly changed to high from the pre-charged voltage by the current mirror 433 and 434, because the local bit line 417 is lowered, which turns on PMOS local read circuit 420 strongly and the segment read circuit 426 is strongly turned on, while the pre-charge transistor 436 is turned off during read. By raising the latch node 435, the inverters 437 and 439 are changed, and the logic states are stored in the latch circuit including two cross coupled inverters 437 and 438. And inverter output signal 439 is transferred to OR gate 446. Furthermore, the OR gate 446 receives multiple signals from other memory block 405, so that the signal is generated only if at least one reference cell works correctly, which signal serves as a reference signal. Then a tunable delay circuit 447 adds a delay time for optimizing the reference signal. Thus, the tunable delay circuit output 448 serves as a locking signal to lock the latch circuits 480 in the main memory block 450 and 451, where the main memory blocks 450 and 451 include same configuration as the reference memory block 400 and 405, except the stored data in the reference memory block 400 is fast data to generate the reference signal. Thus the main memory blocks 450 and 451 receive the locking signal 448 in order to reject slow data. The latch output 483 is connected to output latch circuit or external port (not shown). And output 449 from the memory block 400 is connected to an inverter 402 to compensate the polarity for write-back operation.

On the contrary, when reading data “0”, the feedback transistor 482 of the block read circuit 480 in main memory block 450 is turned off by the locking signal 448 from reference memory block 400 and 405, thus the latch output 483 is not changed even though the block read line 481 is slowly changed by the segment read circuit 476 while the local read circuit 470 is weakly turned on. And more main memory blocks, such as another main memory block 451, can be added to increase density. Advantage of using current mirror as a block read circuit is that the current path is cut off by a direct feedback of the current mirror, which reduces current consumption with short feedback path during read operation. This configuration is more useful when the memory block is relatively small.

In FIG. 5, alternative configuration including a current mirror as a block read circuit in a memory bank including multiple memory blocks is illustrated. Memory blocks 500, 550, 581 and 582 configure a relatively big memory bank, and more memory segments can be added to configure bigger memory bank. The memory block 500 includes memory segment 510 and 519 including a local read circuit, a segment read circuit 526, a block read circuit 530, and a write buffer 501. The memory segment includes a pre-charge transistor 511 to set the local bit line 517, and another pre-charge transistor 521 sets a common line 524. In addition, a common write transfer transistor 525 is connected to the common line 524, in order to share (bit line) transfer transistor 515 for write and read. When writing, the transfer transistors 515 and 525 may be raised to higher than VDD+VT voltage, and also a word line of the memory cell is raised to higher than VDD+VT voltage, to avoid NMOS threshold voltage drop. And the local read circuit is composed of a pre-charge transistor 521, a read transistor 522 and a select transistor 523 for amplifying bit line voltage 517 through the common line 524. And the segment read circuit 526 is composed of a reset transistor 528 and a segment amplify transistor 529 for amplifying the current output from the local read circuit through the segment read line 527, in particular, the segment amplify transistor 529 uses a p-n-p bipolar transistor in order to obtain high gain, where the reset transistor 528 resets the base of the bipolar transistor 529 to VDD voltage in order to reduce leakage current of the bipolar transistor when unselected.

The block read circuit 530 is composed of a current mirror circuit and a latch circuit, wherein the current mirror circuit is composed of a pull-down transistor 533 and a current repeater 534, and the latch circuit is composed of two cross coupled inverters 537 and 538. Alternatively, the pull-down strength of the current repeater is tunable with multiple repeaters including NMOS 545 which is selected by NMOS switch 544, and more current repeaters can be added even though the drawing illustrates only one selectable repeater, which realizes a tunable current mirror. The pull-down transistor 533 is connected to the bipolar segment read circuit 526 through the block read line 549 and NMOS switch 531, and a pre-charge transistor 532. When fast data is read, the bipolar segment read circuit 520 quickly pulls up the block read line 549 while the switch 531 is turned on and the pre-charge transistor 532 is turned off. Hence, the latch node 535 is changed to low from the pre-charged voltage, where the pre-charge transistor 536 is turned off during read. By lowering the latch node 535, the inverters 537 and 539 are changed, and the logic state is stored in the cross coupled inverters 537 and 538.

Then the latched data 546 disables a tri-state inverter 540 and the latched data 546 turns on PMOS 541. Turning on PMOS 541, output of inverter 542 is changed to low from high, such that an output multiplexer is consisted of PMOS 541, the read inverter 542 and the tri-state inverter 540, in order to send the read output. And the read output is transferred to the latch control circuit 575 through the read path including tri-state inverter 551, inverters 552 and 553, non-inverting buffers 554 and 547, where the latch control circuit 575 is the same circuit as 275 in FIG. 2, including a latch circuit 560 and locking signals 572 and 574. As a result, the locking signals 572 and 574 are generated to lock latch circuit 580. In order to write data, a write buffer receives input data from a selector 577, such that external input 576 is selected to modify the memory cell data or the read output 568 is selected to write back by a select control signal 578. Advantage of using current mirror as a block read circuit is that the current path through the segment read circuit is directly cut off by its own feedback of the output of the current mirror, which reduces more current consumption during read operation with very short feedback path.

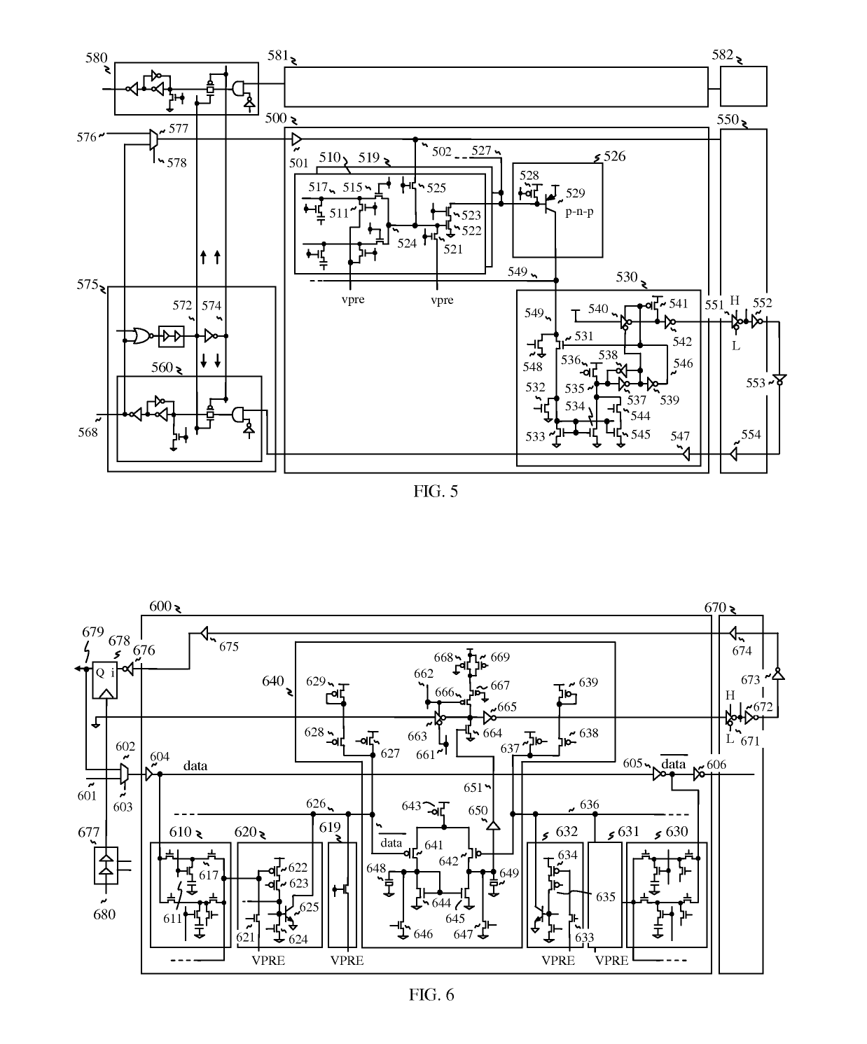

In FIG. 6, alternative configuration with a comparator as a block read circuit is illustrated, wherein a comparator 640 is composed of a differential amplifier. The comparator 640 receives a pairs of block read lines 626 and 636 from selected memory segment 610 and unselected memory segment 630, respectively. A local read circuit 620 configures an amplifier with pull-up transistors 627, 628 and 629 as active loads, such as “common-emitter amplifier”. Thereby the amplifier output 626 serves as the block read line, which amplifies the potential of a selected local bit line 617. And the local bit line 617 is driven by a selected memory cell 611. The selected local read circuit 620 is composed of a pre-charge transistor 621, a read transistor 622, a select transistor 623, a reset transistor 624 and a bipolar transistor 625 to amplify the local bit line voltage. On the contrary, another input 636 for the comparator 640 is generated by a reference circuit 632, which is composed of same circuit as the local read circuit 620, but a reference signal is asserted to the read transistor 634 through the pre-charge transistor 633 which is always turned on and receives pre-charge voltage VPRE (for example, half VDD voltage). And the select transistor 635 is turned on for generating a reference voltage 636, which configure an amplifier with pull-up transistors 637, 638 and 639. And unselected memory segment 630 and unselected local read circuit 631 keep pre-charge state. Furthermore, the amplifiers are tunable with selecting the pull-up strength of the transistors 628 and 638 in order to get the reference voltage near half VDD voltage. Thereby, the local read circuit pulls down the amplifier output 626 lower than half VDD when the local bit line voltage is VPRE-DV voltage as explained above. Otherwise, the local read circuit pulls up the amplifier output 626 higher than half VDD when the local bit line voltage is VPRE+DV voltage, while the reference voltage is near half VDD voltage. And more tunable pull-up transistors can be added even though the drawing illustrates two pull-up transistors. In this manner, the differential amplifier differentiates data “1” and “0” with the mid level reference voltage, so that accurate sensing is achieved for small voltage difference, even though the amplifier and the differential amplifier consume current during read operation.

After the amplifier outputs 626 and 636 are settled down, the pre-charge transistors 646 and 647 of differential amplifier are turned off, and then the differential amplifier is activated by turning on pull-up PMOS 643. Hence, one of receiving transistors 641 and 642 quickly pulls up its drain node, while the other transistor pulls down, because of input voltage difference from the block read lines 626 and 636 which are generated by the amplifiers. The differential amplifier has two inputs, so that one input is referred to as a negative input and another input is referred to as a positive input. In order to keep positive polarity, the memory segment 610 stores positive data because the local read circuit 620 inverts the polarity but the differential amplifier inverts the polarity again. Thereby, output from the differential amplifier is recovered to positive polarity. For example, when the stored data in the memory cell 611 is data “0”, the selected local bit line 617 is slightly discharged from half VDD voltage because the storage node of the memory cell stores low voltage, such that the amplifier output 626 is slightly raised from low voltage, while the reference input from the reference signal generator 636 keeps near half VDD voltage. Hence, the differential amplifier generates low voltage, because the input 626 is lower than the input 636 (near half VDD), where active load 641 is in low impedance state and active load 642 is in high impedance state with input voltage difference. By activating the differential amplifier, the drain node of the receiving transistor 641 and 642 start changing, but the decoupling capacitors 648 and 649 react to change the drain nodes, so that the decoupling capacitors effectively suppress abrupt change when activated, which helps to reject coupling noise. The decoupling capacitor size can be decided depending on the target speed because big capacitor delays the sensing speed while small capacitor does not help filtering noise. After then, the differential output is determined by a non-inverting buffer 650, such that the buffer output 651 keeps low because active load 642 is in high impedance state. Thereby, the positive receiving transistor 642 pulls down its drain node, while the negative receiving transistor 641 pulls up its drain node. And NMOS active load 644 pulls up its drain node, so that another active load 645 keeps low impedance state. As a result, the output of the differential amplifier generates near “low” output, thus the buffer 650 keeps pre-charge state “low”.

On the contrary, when the stored data in the memory cell 611 is data “1”, the buffer 650 generates full high voltage such that the local read circuit 620 is weakly turned on which raises the block read line 626 near VDD voltage, while the reference input 636 keeps near half VDD voltage. Hence, the receiving transistor 641 is in high impedance while the receiving transistor 642 to have low impedance. The buffer 650 can be composed of two inverters. Alternatively, the buffer 650 can be a Schmidt trigger to determine output voltage more effectively. When the memory segment 630 in the right side is selected, the reference voltage generator circuit 619 in the left side is activated. And the memory segment 630 stores negative data, so that an inverting write buffer 605 inverts output of write buffer 604, and another inverting write buffer 606 inverts again for the next block.

After the differential amplifier generates read output 651, a pull-down transistor 664 receives the read output 651 from the differential amplifier, so that an output of an inverter 665 is changed to high only if the output 651 is raised to high otherwise the output of the inverter 665 keeps low, because the pull-down transistor 664 is fully turned on when the read data from the selected memory cell of the memory segment 610 is high, where the strength of pull-up transistors including 666, 667, 668 and 669 is much weaker than that of the pull-down transistor 664. Thereby, the pull-down transistor 664 pulls down its drain only if the read data is “1”, which configures another amplifier with pull-up transistors. Otherwise, the pull-down transistor is turned off and the pull-up transistors sustain the input of inverter 665 to high, and the tri-state inverter 663 in the selected memory block 600 is turned off for the selected block by block select signals 661 (high) and 662 (low). In contrast, the tri-state inverter 671 in the unselected memory block 670 is turned on to bypass the read output. Furthermore, the pull-up strength is tunable with selectable PMOS transistor 669 including wide channel width, where more tunable pull-up transistors can be added even though the drawing illustrates only one tunable circuit. In doing so, weak turn on of the pull-down 664 is rejected by the pull-up transistors, such that the differential amplifier output is very slightly raised when the differential amplifier is activated typically, because both amplifier outputs moves toward half VDD voltage thus the drain nodes of the receiving transistors are slightly raised. The tunable pull-up transistors effectively reject the weak turn-on during transition time. And furthermore, the slight change is rejected by the buffer 650 including a Schmidt trigger as well. When read data “1”, the read buffer 665 transfers the change to the output latch circuit 678, through read path including tri-state inverter 671, inverting buffers 672 and 676, and non-inverting buffers 673 and 674. Then, the read output is stored in the latch circuit 678, and the latch control circuit 677 locks the latch circuit 678, where the latch control circuit 677 receives a read enable signal, and which signal is delayed by a tunable delay circuit in the latch control circuit 677 for optimizing locking time. And reverse configuration is also available with p-n-p bipolar segment read circuit (not shown), such that the configuration for the differential amplifier is also reversed with NMOS receiving transistors for the differential amplifier.

In FIG. 7A, more detailed a tunable delay circuit (as shown 271 in FIG. 2) is illustrated, wherein multiple delay units 701, 702 and 703 are connected in series, the first delay unit 701 receives input IN and generates output OUT, the second delay unit 702 is connected to the first delay unit, and the third delay unit 703 is connected to the second delay unit 702 and generates outputs 704 and 705, and so on. Each delay unit receives a fuse signal, such that the first delay unit receives F0, the second delay unit receives F1, and the third delay unit receives F2. And more detailed delay unit is illustrated in FIG. 7B, wherein the delay unit 710 receives an input IN0 and a fuse signal Fi, thus the fuse signal Fi selects output from the input IN0 or input DL1, so that a transfer gate 711 is turned on when the fuse signal Fi is low and output of inverter 713 is high, otherwise another transfer gate 712 is turned on when the fuse signal Fi is high and output of inverter 713 is low to bypass DL1 signal. Inverter chain 714 and 715 delays IN0 signal for the next delay unit, where more inverter chains or capacitors can be added for the delay even though the drawing illustrates only two inverters.

In FIG. 7C, a related fuse circuit of the tunable delay circuit (as shown in FIG. 7A) is illustrated in order to store information for the delay circuit, so that a fuse serves as a nonvolatile memory, wherein a fuse 721 is connected to a latch node 722, a cross coupled latch including two inverters 725 and 726 are connected to the latch node 722, pull-down transistors 723 and 724 are serially connected to the latch node 722 for power-up reset. Transfer gate 730 is selected by a select signal 729 (high) and another select signal 728 (low) in order to bypass the latch node voltage 722 through inverter 725 and 727. In doing so, fuse data is transferred to output node Fi, otherwise test input Ti is transferred to Fi when a transmission gate 731 is turned on.

In FIG. 7D, a detailed selector circuit is illustrated for selecting external input data or internal refresh data for the selector circuit 278 as shown in FIG. 2, wherein external input 776 is selected when a select control signal 778 is asserted to high, or the read data 768 from the memory cell is selected when a select control signal 778 is asserted to low.

### METHODS OF FABRICATION

The memory cell can be formed on the surface of the wafer. And the steps in the process flow should be compatible with the current CMOS manufacturing environment as the prior arts, such as U.S. Pat. No. 6,297,090, No. 6,573,135 and No. 7,091,540 for forming DRAM memory cell. Alternatively, the memory cells can be formed in between the routing layers. In this manner, fabricating the memory cells is independent of fabricating the peripheral circuits on the surface of the wafer. In order to form the memory cells in between the metal routing layers, LTPS (Low Temperature Polycrystalline Silicon) can be used, as published, U.S. Pat. No. 5,395,804, U.S. Pat. No. 6,852,577 and U.S. Pat. No. 6,951,793. The LTPS has been developed for the low temperature process (around 500 centigrade) on the glass in order to apply the display panel, according to the prior arts. Now the LTPS can be used as a thin film polysilicon transistor for the memory device. The thin film based cell transistor can drive multi-divided bit line which is lightly loaded, even though thin film polysilicon transistor can flow less current than single crystal silicon based transistor on the surface of the wafer. For example, the thin film polysilicon transistor is around 10 times weaker than that of conventional transistor, as published, “Poly-Si Thin-Film Transistors: An Efficient and Low-Cost Option for Digital Operation”, IEEE Transactions on Electron Devices, Vol. 54, No. 11, Nov, 2007, and “A Novel Blocking Technology for Improving the Short-Channel Effects in Polycrystalline Silicon TFT Devices”, IEEE Transactions on Electron Devices, Vol. 54, No. 12, December 2007. During LTPS process, the MOS transistor in the control circuit and routing metal are not degraded. In this respect, detailed manufacturing processes for forming the memory cells, such as width, length, thickness, temperature, forming method, or any other material related data, are not described in the present invention.

In FIGS. 8A, 8B, 8C and 8D, example layouts for configuring memory cell array are illustrated. A solid line 800 depicts two identical memory cells, where two memory cells are symmetrically formed in order to share an active region 801. In the process steps, the active region 801 is formed first, and gate oxide (not shown) is formed on the active region, then gate region 802 is formed on the gate oxide region. After then capacitor contact region 803 is formed as shown in FIG. 8A. Then, a storage node 804 is formed on the capacitor contact region 803 as shown in FIG. 8B. After forming the storage node (bottom plate) 804, an insulation layer (not shown) is formed on the storage node 804. Then, a capacitor plate (top plate) 805 is formed on the storage node 804 as shown in FIG. 8C. After then, metal contact region 806 is formed. In FIG. 8D, first metal layer 807 for the local bit line is formed on the metal contact region 806 in FIG. 8C. And second metal layer 821 for global word line is formed on the first metal layer 807, as shown in FIG. 8D.

More detailed bit line structure is illustrated in FIG. 9, wherein a memory cell pair 911 in a memory segment 910 is connected to the local bit line 912, the common line 924 is connected to the bit line 912 through the read transfer transistor 915 and also connected to the local read circuit 920 to read the memory cell, and the segment write line 901 is connected to the local bit line through write transfer transistor to write data. And another memory segment 950 includes another local read circuit 920A connecting multiple memory cells. Thereby, the segment read circuit 926 is connected to multiple local read circuits including 920 and 920A through the segment read line 927. And a write buffer (not shown) is also shared by multiple local bit lines in the similar manner.

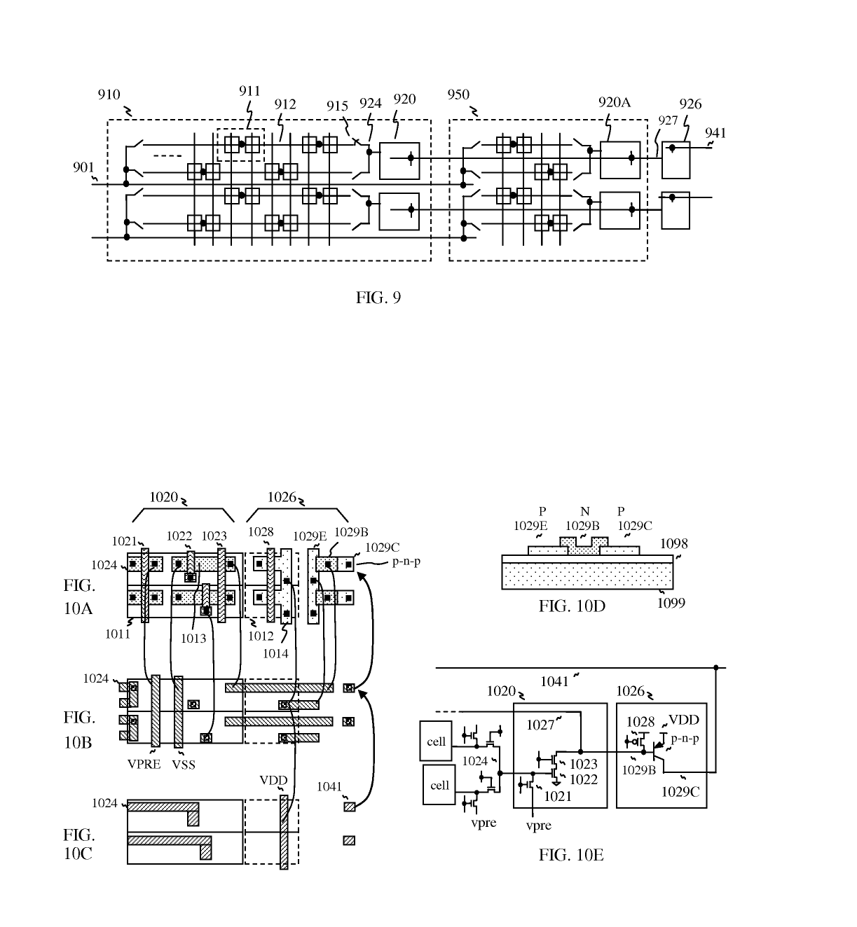

In FIGS. 10A to 10C, example layout for the local read circuit and the segment read circuit is illustrated, wherein the local read circuit (the first amplifier) 1020 is placed next to memory cells (not shown) and the segment read circuit (the second amplifier) 1026 are placed next to the local read circuit 1020. The local read circuit 1020 includes poly gate 1021 as a pre-charge transistor, poly gate 1022 as a read transistor and poly gate 1023 as a select transistor, which transistors are composed of n-type active region 1013 on the p-well region 1011. The reset transistor 1028 is connected to the base of the bipolar transistor which is composed of p-type emitter 1029E, n-type base 1029B and p-type collector 1029C. A vertical structure for the bipolar transistor the field oxide 1098 which is attached to the substrate 1099, such that p-type regions including emitter region 1029E and collector region 1029C are formed first, then n-type base region 1029B is deposited on the emitter and collector region. And also various fabrication methods can be used to form the bipolar transistor in order to fit the cell pitch. Furthermore, the bipolar transistor need not be a high performance device nor have a high current gain. The equivalent circuit including the local read circuit 1020 and the segment read circuit 1026 is shown in FIG. 10E wherein the local read circuit 1020 is connected the memory cells, the segment read circuit 1026 is connected to the local read circuit 1020, the base 1029B serves as the segment read line 1027, the collector 1029C is connected to the block read line 1041, and the node numbers are the same as FIG. 10A for ease of understanding. And metal-1 layer and via-1 are defined as shown in FIG. 10B. And in FIG. 10C, metal-2 layer is defined, such that the common read line 1024 is connected to the local read circuit 1020, the base region of the bipolar transistor is connected to the output of the local read circuit 1020, and the block read line 1041 is defined to be connected to n-type collector region 1029C through metal-1 region.

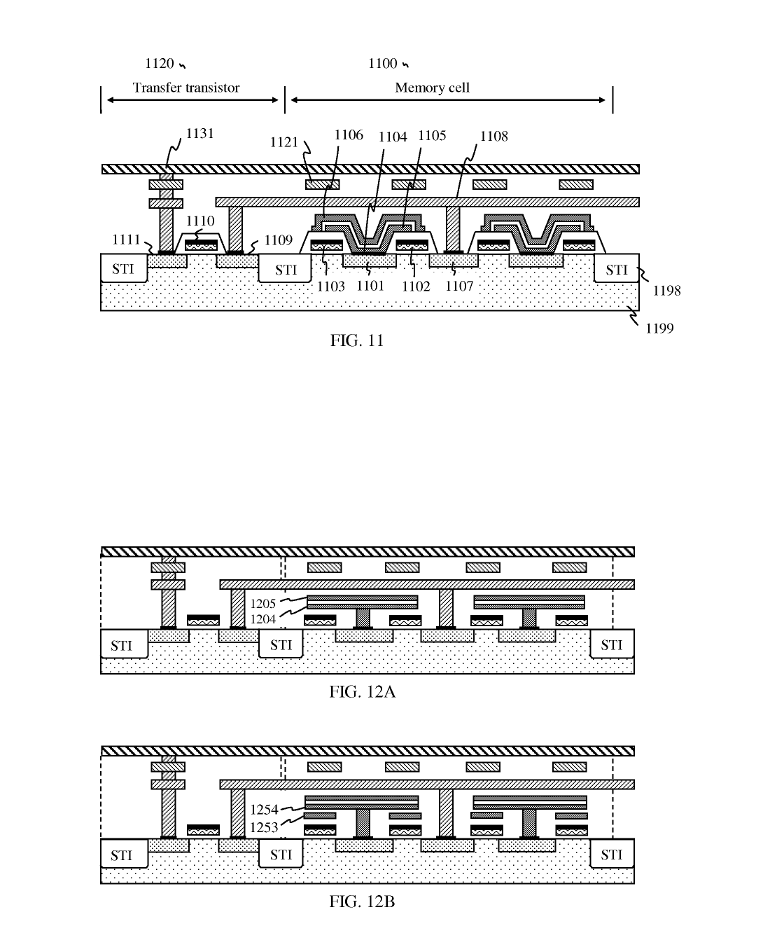

FIG. 11 illustrates an example cross sectional view for the memory cell for obtaining high capacitance, wherein a capacitor is composed of bottom plate 1105 and top plate 1106 on the gate region, and the capacitor is connected to a drain/source 1101 of a transfer gate 1102 through contact region 1104. And bit line 1108 is connected to a drain/source 1107 of the transfer gate 1102. Thus memory cell data is transferred to local bit line 1108 which is composed of metal-1 layer and the local bit line is connected to a write transfer transistor 1110 through drain 1109 and source 1111. Then, source 1111 of the write transfer transistor 1110 is connected to a write data line 1131 which is composed of metal-3 layer, where global word line 1121 passes under the write data line 1131. The peripheral circuit region 1120 is placed on the same surface of a substrate 1199, where the memory cell area 1100 is isolated by STI (Shallow Trench Isolation) region 1198. In terms of the storage capacitor, the effective area of the capacitance is increased with three-dimensional structure on the gate region, but there is slight coupling with selected word line (gate) 1102 and passing word line 1103. The coupling noise is negligible only if total storage capacitance is much bigger than the coupling capacitance.

FIG. 12A illustrates an example cross sectional view for the memory cell including flat plates, wherein the flat plates 1204 and 1205 configure a capacitor, such that the capacitor serves as a storage element for storing charges. And this structure has coupling noise with word lines but the coupling is negligible portion only if the total capacitance of the capacitor is enough big with good dielectric material. For example, DRAM uses ordinary dielectric capacitor, such as silicon dioxide, silicon nitride, Ta2O5, TiO2, Al2O3, TiN/HfO2/TiN(TIT), and Ru/Insulator/TiN(RIT). And MIM (Metal Insulator Metal) structure can be used for forming the capacitor. Alternatively, ferroelectric capacitor can be used as a storage capacitor, such as lead zirconate titanate (PZT), lead lanthanum zirconium titanate (PLZT), barium strontium titanate (BST), and strontium bismuth tantalate (SBT), where dielectric constant of ferroelectric capacitor is typically high so that effective capacitance is increased.

FIG. 12B illustrates an example cross sectional view for the memory cell including one more plate 1253, wherein additional plate 1253 is formed under the storage plate 1254. Thereby, the storage node 1254 is isolated from the gate layer, which eliminates the coupling noise from the word line. Furthermore total capacitance is increased with the additional plate 1253 which is connected to a constant voltage source. And other layers are the same as the structure as shown in FIG. 11.

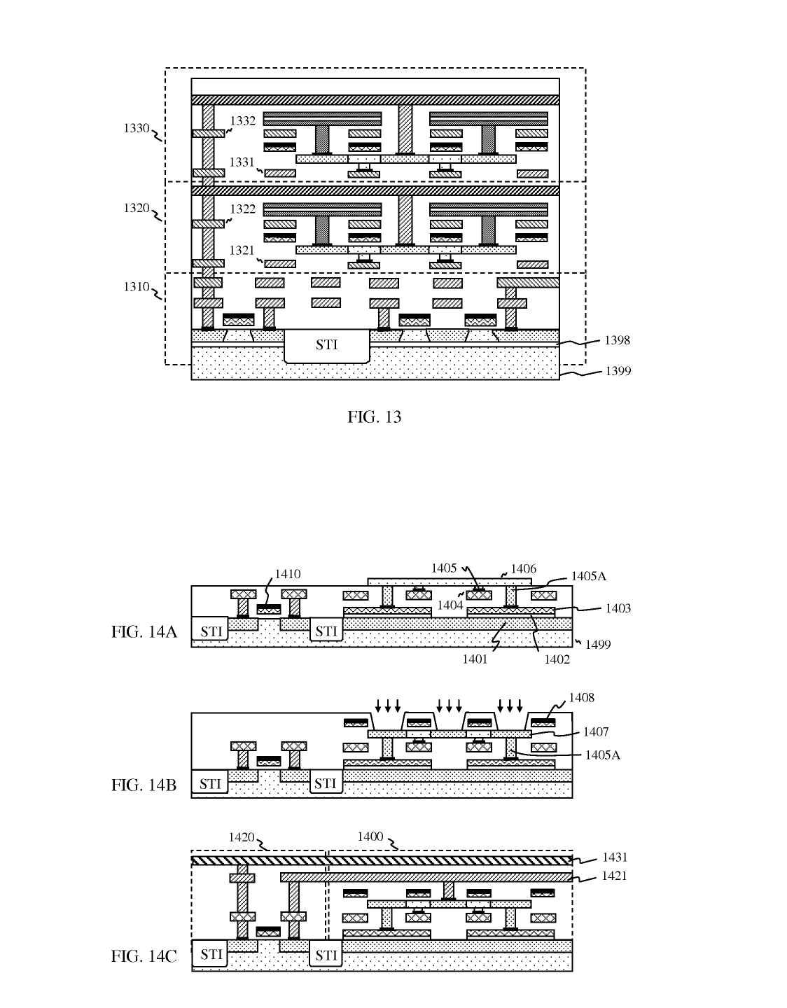

In FIG. 13, another cross sectional view is illustrated, where the peripheral circuit 1310 is formed on insulation layer 1398 of the SOI (Silicon on Insulator) wafer 1399. The memory cell 1320 is stacked over the first floor 1310 and another memory cell 1330 is stacked over the second floor. And the memory cell structure is similar to that of FIG. 12B, but thin film polysilicon transistor, such as LTPS layer, is used as the pass transistor for stacking multiple memory cells. And the metal layer 1321 and 1331 are formed for biasing the pass transistors. And the metal layers 1322 and 1332 are also used to reduce the depth of the metal contacts for forming the memory cells.

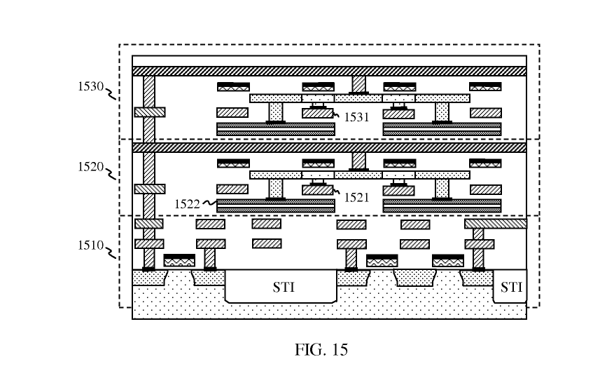

In FIGS. 14A, 14B and 14C, an alternative structure is illustrated, wherein the storage capacitor is formed on the active region 1401 in the substrate 1499 to increase the capacitor area with no contact space. Hence, the storage plate 1403 is formed on the insulation layer 1402 and then metal layer 1404 is formed in order to connect the body of the pass transistor, where (p-type) polysilicon layer 1406 is formed on the metal layer 1404. Separately, poly region 1410 is deposited for forming write transfer transistor. Thereby the polysilicon layer 1406 is connected to the metal layer 1404 through contact region 1405 including same type of polysilicon through an ohmic contact region. And storage node is connected to the polysilicon layer 1406 through a contact region (n-type contact plug) 1405A, which contact is separately formed, as shown in FIG. 14A. After then, in FIG. 14B, poly gate region 1408 is formed, and the active region 1407 is counter-doped (n-type), which region is also connected to the storage contact region 1405A with same type of (n-type) polysilicon. Then, in FIG. 14C, local bit line 1421 is formed, and a write data line 1431 is formed on the local bit line 1421, where memory cell region 1400 and peripheral circuit (transfer transistor) region 1420 are illustrated for clarifying the cross sectional view.

In this structure, peripheral circuit 1420 is formed on the surface of the wafer 1499, but the memory cell 1400 is formed from polysilicon layer, so that the body should be connected to a bias voltage through metal layer 1404, for instance, to a negative voltage, in order to reduce sub-threshold leakage current of the pass transistor. The metal layer 1404 can be formed from tungsten in order to form the pass transistor with high temperature polysilicon which is formed at 1100 centigrade typically, because melting point of tungsten is typically much higher than aluminum or copper, thus tungsten is used for forming DRAM cell, even though sheet resistance of tungsten is higher than regular metal routing layer. Alternatively, the metal layer 1404 can be formed from aluminum or copper with low temperature polysilicon (around 500 centigrade) for forming the pass transistor.

In FIG. 15, a cross sectional view is shown, in order to stack multiple memory cells on the peripheral circuits 1510 with thin film polysilicon pass transistors using LTPS layer, where the memory cell 1520 is stacked over the peripheral circuits and another memory cell 1530 is stacked over the second floor. And the memory cell structure is the same as that of FIG. 13C except tungsten layer for the bias voltage is converted to regular routing layer (aluminum or copper) for reducing sheet resistance. The storage node 1522 of the memory cell is isolated from other routing layers, which realizes to reduce coupling noise. And the metal layer 1521 and 1531 are formed for biasing the body of the pass transistor, and which layer can be used as regular routing layer for the peripheral circuits. Furthermore, leakage current is reduced by forcing negative voltage for the n-type biased pass transistor.

While the descriptions here have been given for configuring the memory circuit and structure, alternative embodiments would work equally well with reverse connection such that PMOS transistor can be used as a pass transistor for configuring the memory cell, and signal polarities are also reversed to control the reverse configuration.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

What is claimed is:

1. A memory device, comprising:
a memory cell including a pass transistor and a capacitor; and
a memory segment, wherein a plurality of memory cell is connected to a bit line which is connected to a write transfer transistor and a read transfer transistor; and
a local read circuit, wherein a local amplify transistor receives an output from one of multiple memory segments through a common line which is connected to the read transfer transistor of the memory segment, a pre-charge transistor is connected to the common line, a select transistor is serially connected to the local amplify transistor, and the select transistor is enabled when selected; and
a segment read circuit, wherein a segment amplify transistor receives an output from one of multiple local read circuits through a segment read line, and a reset transistor resets the segment read line when unselected; and
a block read circuit, wherein a current mirror receives an output from one of multiple segment read circuits through a block read line and a feedback transistor for generating an output to a latch device, the feedback transistor is controlled by an output of the latch device; and also the output of the latch device is transferred to a multiplexer wherein a send transistor receives the output of the latch device, a read inverter is connected to an output of the send transistor and an output of a tri-state inverter which is controlled by the output of the latch device, and a read output of the read inverter is determined by the output of the latch device; and
a read path including multiple buffers to transfer the read output; and
a latch circuit receiving the read output through the read path and storing the read output; and
a latch control circuit generating a locking signal which is generated by a reference signal based on a reference memory cell, in order to lock the latch circuit.

2. The memory device of claim 1, wherein the local amplify transistor of the local read circuit is connected to a common line which is connected to multiple memory segments wherein a transfer transistor is connected to a bit line, a pre-charge transistor is connected to the bit line, and a plurality of memory cell is connected to the bit line; and the common line is connected to a common write transfer transistor for writing data through the transfer transistor.

3. The memory device of claim 1, wherein the local amplify transistor of the local read circuit is composed of a low threshold MOS field effect transistor.

4. The memory device of claim 1, wherein the segment amplify transistor of the segment read circuit is composed of various types of transistor, such as a MOS field effect transistor, a low threshold MOS field effect transistor and a bipolar transistor.

5. The memory device of claim 1, wherein the block read circuit includes a current mirror, a latch device and a multiplexer, such that an active load is connected to multiple segment read circuits through a block read line and a feedback transistor, a current repeat transistor is connected to the active load to configure the current mirror, and an output of the current mirror is stored to the latch device; and a first pre-charge transistor is connected to the block read line, a second pre-charge transistor is connected to the active load, a third pre-charge transistor is connected to the output of the current mirror, and the feedback transistor is controlled by an output of the latch device; and also the output of the latch device serves as a read output.

6. The memory device of claim 1, wherein the block read circuit includes a tunable current mirror, a latch device and a multiplexer, such that an active load is connected to multiple segment read circuits through a block read line and a feedback transistor, multiple current repeat transistors are connected to the active load to configure the tunable current mirror, and an output of the current mirror is stored to the latch device; and a first pre-charge transistor is connected to the block read line, a second pre-charge transistor is connected to the active load, a third pre-charge transistor is connected to the output of the tunable current mirror; and the feedback transistor is controlled by the output of the latch device; and also the output of the latch device is transferred to the multiplexer wherein a send transistor receives the output of the latch device, a read inverter is connected to an output of the send transistor and an output of a tri-state inverter which is controlled by the output of the latch device, and a read output of the read inverter is determined by the output of the latch device; and tuning information for the tunable current mirror is stored in a nonvolatile memory.

7. The memory device of claim 1, wherein the block read circuit includes a load transistor and a multiplexer, such that the load transistor is connected to multiple segment read circuits through a block read line and transfer transistors; and the load transistor is connected to the multiplexer wherein a read inverter receives a voltage output of the load transistor, and the read inverter generates a read output, where an output node of a tri-state inverter is connected to the load transistor for multiplexing an output from the other multiplexer.

8. The memory device of claim 1, wherein the block read circuit includes a tunable active load and a multiplexer, such that the tunable active load having multiple load transistors is connected to multiple segment read circuits through a block read line and transfer transistors; and the tunable active load is connected to the multiplexer wherein a read inverter receives a voltage output of the tunable active load, and the read inverter generates a read output, where an output node of a tri-state inverter is connected to the tunable active load for multiplexing an output from the other multiplexer; and tuning information for the tunable active load is stored in a nonvolatile memory.

9. The memory device of claim 1, wherein the block read circuit includes a differential amplifier, such that a pair of input transistors of the differential amplifier is connected to a pair of block read lines where one block read line receives an output from one of multiple segment read circuits through a block read line, and another block read line receives a reference signal from a reference voltage generator.

10. The memory device of claim 1, wherein the read path includes a returning path.

11. The memory device of claim 1, wherein the latch control circuit receives a read enable signal from a control circuit and generates a locking signal to lock the latch circuit.

12. The memory device of claim 1, wherein the latch control circuit includes a tunable delay circuit, such that the tunable delay circuit receives multiple reference signals which are generated by multiple reference memory cells; and the tunable delay circuit generates a locking signal by delaying at least one reference signal from the multiple reference signals.

13. The memory device of claim 1, wherein the memory cell is formed on peripheral circuits.

14. The memory device of claim 1, wherein the memory cell is stacked over another memory cell.

15. The memory device of claim 1, wherein the pass transistor of the memory cell is formed from thin film polycrystalline silicon.

16. The memory device of claim 1, wherein the pass transistor of the memory cell is controlled by a word line which has two states where one of the states is higher than supply voltage of the block read circuit.

17. The memory device of claim 1, wherein the capacitor of the memory cell includes multiple layers for forming the capacitor, such as polysilicon-insulator-polysilicon capacitor and metal-insulator-metal capacitor.

18. The memory device of claim 1, wherein the capacitor of the memory cell is formed from ordinary dielectric material, such as silicon dioxide, silicon nitride, Ta2O5, TiO2, Al2O3, TiN/HfO2/TiN(TIT), and Ru/Insulator/TiN(RIT); and the capacitor is formed from ferroelectric material, such as lead zirconate titanate (PZT), lead lanthanum zirconium titanate (PLZT), barium strontium titanate (BST), and strontium bismuth tantalate (SBT).

19. The memory device of claim 1, wherein the capacitor of the memory cell includes a bottom plate, a middle plate and a top plate, where the middle plate serves as a storage node of the memory cell while the bottom plate and the top plate are connected to constant voltage.

20. The memory device of claim 1, wherein the capacitor of the memory cell is formed under the pass transistor.
